(19) United States
(12) Patent Application Publication
(10) Pub. No.: US 2009/0175019 A1
(43) Pub. Date: Jul. 9, 2009

(54) CIRCUIT-BOARD MODULE AND MANUFACTURING METHOD

(76) Inventors: Keiji Koyama, Osaka (JP); Masamichi Yamamoto, Osaka (JP); Katsunari Mikage, Osaka (JP); Jin-Joo Park, Osaka (JP)

Correspondence Address: MCDERMOTT WILL & EMERY LLP, 600 13TH STREET, N.W., WASHINGTON, DC, 20005-3096, US

(21) Appl. No.: 12/299,561

(22) PCT Filed: Feb. 8, 2008
(86) PCT No.: PCT/JP2008/052174

§ 371 Date: Nov. 4, 2008

(30) Foreign Application Priority Data
Mar. 20, 2007 (JP) 2007-072720

(51) Int. Cl. H05K 1/14; H01L 21/98

(52) U.S. Cl. 361/803; 438/107; 257/E21.705

(57) ABSTRACT

[Problem]

To enable mounting a part on the rear surface at the back of a connection part on a PCB to be connected with a FPC.

[Means for Solving the Problem]

Connection parts are provided such that a conductor wiring of a first circuit board and a conductor wiring of a second circuit board are connected with an anisotropic conductive adhesive which is made of an insulative resin including needle-shaped or linear chain-shaped metal powders oriented in a thickness direction, i.e., adhesion direction, and a part is mounted on at least either one of the first and the second circuit boards, the part being mounted on the rear surface at the back opposed to the surface where the connection part is formed.

### TECHNICAL FIELD

The present invention relates to circuit-board modules used as a part of electronic equipment and methods of manufacturing them. In particular, the circuit-board modules of the present invention, which comprise a flexible printed-circuit board (FPC), a flexible flat cable (FFC), and/or a rigid printed-circuit board (PCB) electrically connected together, are suitable for use in electronic equipment which is down-sized and/or made thinner, such as a mobile phone, camera, etc.

### BACKGROUND ART

In recent years, the reduction in the size, thickness, and weight of electronic equipment has been facilitated. Accordingly, in a circuit board used in such electronic equipment, the conductor pitch has been made smaller to a pitch of 1 mm or less, and further to a pitch of 0.2 mm or less, and for example, a rigid circuit board made of a PCB having conductors arranged in such a narrow pitch is electrically connected with a circuit board made of a flexible FPC, FFC, or the like.

For the purpose of connecting conductors of these circuit boards, the following electrical connection methods have been mainly adopted in the past: connection is achieved by inserting FPC conductors into terminals in a connector provided on a PCB; connection is achieved by direct solder-connection of conductors exposed by peeling off the insulation coatings at the connection parts (Japanese Patent Application Publication No. H8-17259); and connection is achieved by connecting conductors exposed at the connection parts through an anisotropic conductive adhesive (ACF).

Of the electric connection methods mentioned above, the shortcomings of the connection method using a connector are that the circuit board becomes thick due to the thickness of the connector, thereby requiring installation space, and that the number of parts and assembly processes increases, which results in difficulty in adapting to the above-mentioned tendency toward a narrow pitch design of terminals.

Also, the drawback of the direct solder-connection method is that, in a case of redoing the connection work (repair), if damage is caused due to difficulty in peeling-off because of high connection strength, the re-use would be impossible although the electrical connection might otherwise be highly reliable.

In the case of connection using the above-mentioned anisotropic conductive adhesive, a film or paste in which electro-conductive particles are dispersed in an insulative resin is used as the anisotropic conductive adhesive, and oppositely arranged connecters are connected together by heat-pressing. When connection is achieved using the anisotropic conductive adhesive, components can be down-sized because conductor wirings of the printed circuit board can directly be connected together, and also it is possible to adapt to the narrow pitch connection, resulting in more advantages as compared with the case of using a connector.
Patent document 1: Japanese Patent Application Publication No. H 8-17259

### DISCLOSURE OF INVENTION

### Problems to be Solved by the Invention

The connection done using the anisotropic conductive adhesive has the above-mentioned advantages; however, in the case of an anisotropic conductive adhesive available on the market, connection requires pressing at high temperature and a high pressure of 4 MPa or more, thereby large compressive load being applied on the circuit board to be connected. Thus, when conductor wirings of a PCB and conductor wirings of a FPC or a FFC are respectively connected with the anisotropic conductive adhesive, the PCB is subjected to high compressive load since heating and pressure are applied while the FPC or the like is put on the surface of the fixedly positioned PCB. Generally, the PCB is connected to the FPC or the like after an electronic part and/or an electrical part have been mounted thereon, and therefore it is impossible to mount a part on the rear surface at the back opposed to the surface on which the connection with the FPC or the like is done.

If a jig for mounting a packaging part is used, it may be possible to mount a part on the rear surface; however, the space for arranging the jig is hardly available in the case where circuits are also formed at high density on the rear surface, and the jig for mounting the packaging part must be made thinner, and consequently it will be difficult to endure the high compressive load applied at the time of connection. Therefore, it is difficult to mount a part on the rear surface at the back opposed to the connection part. In the case of the above-mentioned connection using a connector, it may be possible to mount a part on the rear surface because no pressure is applied; however, the problem is that the thickness of the connector will make the PCB thicker as described above. Therefore, it is necessary to avoid applying high compressive load to the PCB at the time of connection made by heat-compression using the anisotropic conductive adhesive or the like.

An object of the present invention, which was made from the viewpoint of the above-mentioned problems, is to provide a circuit-board module on which parts are mounted at high density and in which an anisotropic conductive adhesive is used so that the compressive load applied to the circuit board at the time of connection between conductor wirings of the circuit board can be reduced and consequently a part can also be mounted on the rear surface at the back opposed to the connection part.

### Means for Solving the Problems to be Solved

In order to solve the above-mentioned problems, the present invention provides, as a first aspect of the invention, a circuit-board module having connection parts where a conductor wiring of a first circuit board and a conductor wiring of a second circuit board are connected with an anisotropic conductive adhesive, the anisotropic conductive adhesive being made of an insulative resin including needle-shaped or linear chain-shaped metal powders oriented the thickness direction of the adhesive, and where a part is mounted on at least either one of the first and the second circuit boards, the part being mounted on the rear surface at the back opposed to the surface where the connection part is formed.

An anisotropic conductive film set forth in Japanese Patent Application Publication No. 2003-331951, which relates to the preceding application of the present applicant, can suitably be used as the above-mentioned anisotropic conductive adhesive in a manner such that the anisotropic conductive film is interposed between two circuit-boards to be connected together or is attached to the connection parts of one of the circuit boards beforehand, where the electrical connection is achieved by compressing in the thickness direction by means of heat and pressure at the time of connection so that each end of a length of electro-conductive particles, which are combined together in a needle-like shape or linear chain-like shape, is connected to each conductor wiring to be connected.

Since the needle-shaped or linear chain-shaped metal powders are oriented in the thickness direction, the electrical resistance (“connection resistance”) in the thickness direction can be made lower. Moreover, it is possible to prevent a short circuit between adjacent conductor wirings since the distribution density of conductive elements in the anisotropic conductive film through which the metal powders pierce at right angles does not increase in a planar direction and the insulation resistance is high.

More specifically, the above-mentioned metal powders are made by combining minute metal particles of silver, nickel, copper, or the like in a needle shape or linear chain shape, and preferably the average grain size of the metal particles is 400 nm or less. Also, the diameter D of the metal powder made by condensing the metal particles in a needle shape or linear chain shape is preferably 1 μm to 20 μm or less, the length L is preferably less than the distance between conductor wirings of connecting circuit boards to be connected, and the ratio between the thickness and the length of the needle or linear chain is about 10 to 100. Thus, the metal powder is formed in a shape longer in the thickness direction, while the thickness is 1/10 to 1/100 of the length. Therefore, it is unnecessary to make the filing fraction of metal powder so high, and the filling fraction may be 0.05 to 5% by volume.

As described above, the filling fraction of the metal powder can be made low, and therefore it is possible to significantly reduce the connection resistance of the thickness direction as compared with conventional one while maintaining the surface direction insulation resistance of the anisotropic conductive film to be high level. Accordingly, the pressure applied at the time of connection can substantially be reduced. In the conventional anisotropic conductive adhesive, the filling fraction of metal powder is 7 to 10% by volume.

The insulative resin that includes the metal powder may be either a thermosetting resin or a thermoplastic resin provided that the resin is excellent in elasticity, heat resistance, processability, mechanical property, dielectric property, low out-gas property, etc. Examples of such resins include polyester resin, epoxy resin, polyimide resin, aramid resin, fluoro resin, acrylic resin, phenol resin, etc. These resins may be used in one kind or in combination of plural kinds.

As described above, in the present invention, the pressure applied to circuit boards at the time of connection can be substantially reduced because an anisotropic conductive adhesive with which pressure applied at the time of connection can be reduced is used as an adhesive between conductor wirings of circuit boards. As a result, the compressive loading can be sustained by the substrate of the circuit board itself even when a part is mounted on the rear surface at the back opposed to the connection part existing on the surface side of the circuit board. Therefore, it is possible to restrain the load from affecting on the part mounted on the rear surface. Also, even if a load receiving jig is used in the case where the strength (pressure resistance) of the substrate is comparatively low, the supporting member of the load receiving jig to support the circuit board from the back side can be made thinner, and accordingly it is unnecessary to make the open space for the jig so large.

In this manner, it is also possible to mount a part on the rear surface at the back opposed to the connection part in another circuit board. In addition, a part can be mounted on the surface where a connection part for connecting to another circuit board exists. Thus, it is possible to mount parts on both surfaces of a circuit board at high density, whereby the miniaturization of the circuit board can be attempted.

The present invention can suitably be used for a circuit-board module in which the first circuit board consists of a rigid printed-circuit board on which a part such as an electronic part is mounted, and the second circuit board is a flexible printed-circuit board. More specifically, in many cases a plurality of FPCs are connected with sides of a rigid printed-circuit board (PCB) that is housed in electronic equipment. In such a case, if the rear surface at the back opposed to the surface where a plurality of connection parts exist becomes a region where parts can be mounted, the packaging space for mounting the parts can substantially be increased, and accordingly, the miniaturization of the PCB or multi-functionalizing by mounting more parts can be achieved.

Moreover, in the case of a circuit-board module in which a plurality of PCBs are connected together through FPCs, parts can be mounted on the rear surfaces of the PCBs at the back opposed to the connection parts where a connection with each FPC is made. Consequently, the area for mounting parts is increased more, and accordingly it is possible to miniaturize or multi-functionalize the circuit-board module as a whole.

Moreover, the present invention provides electronic equipment in which the above-mentioned circuit-board module is contained. In the case where the circuit-board module includes a PCB as mentioned above, electronic parts and circuit patterns can be formed at high density by mounting electronic parts on the rear surface at the back opposed to the face where connection parts for connecting with a FPC or FFC exist, and therefore it is possible to attempt the miniaturization of the PCB, and consequently the circuit-board module itself can also be downsized, whereby, the miniaturization of the electronic equipment including the circuit-board module can be realized.

Examples of electronic equipment having such circuit-board modules include thin, small-sized, light-weight, and portable electronic equipment, including mobile phone equipment, a camera such as a digital camera or camcorder, a portable audio player, a portable DVD player, a portable laptop, and the like.

Furthermore, the present invention provides a method of manufacturing the circuit-board module.

The manufacturing method comprises steps of:

mounting an electronic part on either of the first circuit board and the second circuit board; and

connecting conductors of the first circuit board and the second circuit board by mutually contacting them on the face opposite to the parts-mounted face through an anisotropic conductive adhesive and by applying thereto a pressure of 2 MPa or less.

As described above, when an electronic part must be mounted on a circuit board to which connection is made, the electronic part is mounted beforehand prior to the connection. Generally, in the case where the circuit board is a PCB, the PCB is connected with the wiring member of a FPC or FFC in a completed condition such that parts are mounted on one or both surfaces of the PCB. Thus, also in the case of the present invention, the connection made through the anisotropic conductive adhesive is done after the mounting of the electronic part.

The anisotropic conductive adhesive used in the present invention includes needle-shaped or linear chain-shaped elements which are oriented in the thickness direction as described above, and consequently the pressure applied to the PCB at the time of connection can be reduced to 2 MPa or less, and further to 0.5 MPa or less.

Therefore, when the substrate such as a PCB has a pressure resistance against the compressive load, the PCB can be connected with the FPC without causing the compressive load to affect the electronic part mounted on the rear surface. On the other hand, when the strength (pressure resistance) of the substrate such as a PCB is comparatively low, a load receiving jig is used. However, the supporting member of the load receiving jig for supporting the circuit board from the back side can be thinner, and accordingly the open space needed for the jig can be made less. Consequently, it is possible to restrain the increase of the substrate area even if an electronic part is mounted on the rear surface at the back opposed to the connection part.

### Advantageous Effect of the Invention

In the present invention, as described above, the connection between conductor wirings of circuit boards is done through an anisotropic conductive adhesive which allows the pressure applied at the time of the connection to substantially be reduced, and consequently a part such as an electronic part can be mounted on the rear surface of the circuit board at the back opposed to the connection part. Accordingly, the region for mounting parts can be enlarged, allowing increase in the number of parts mounted, and thereby the miniaturization or multifunctionalization of the circuit board can be achieved.

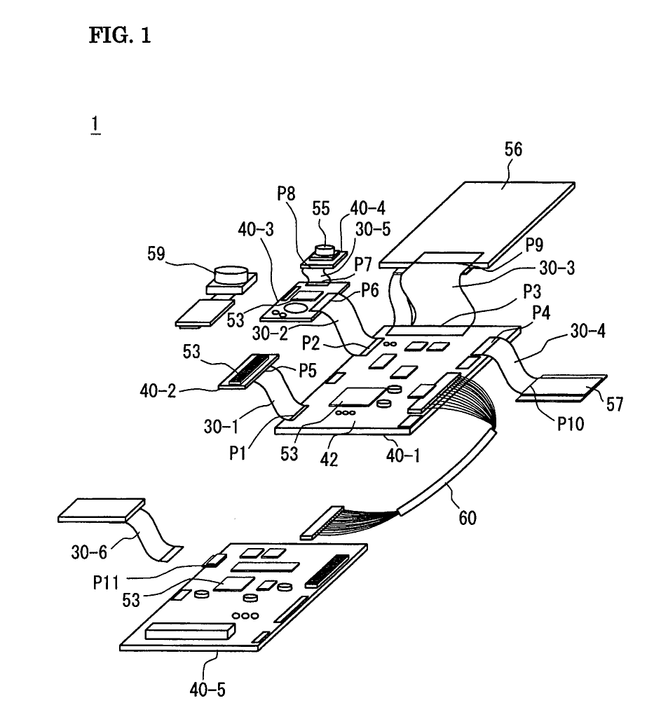

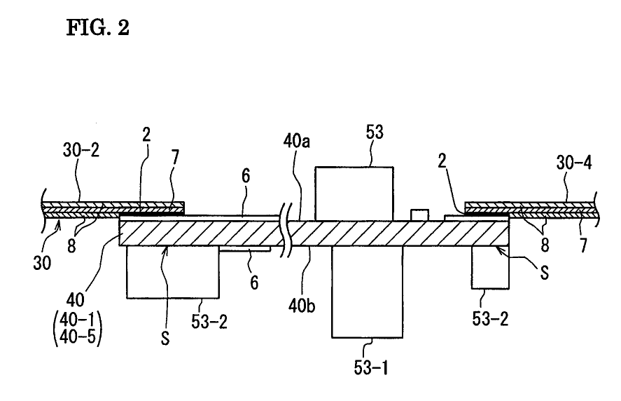

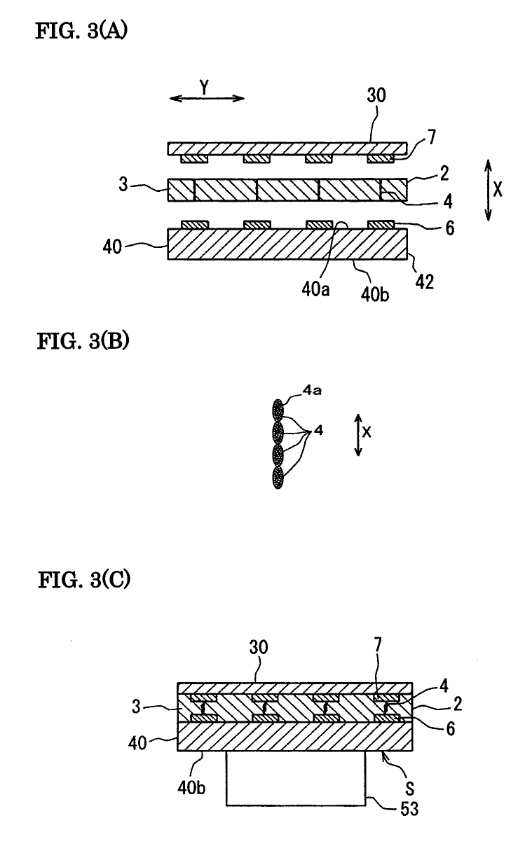

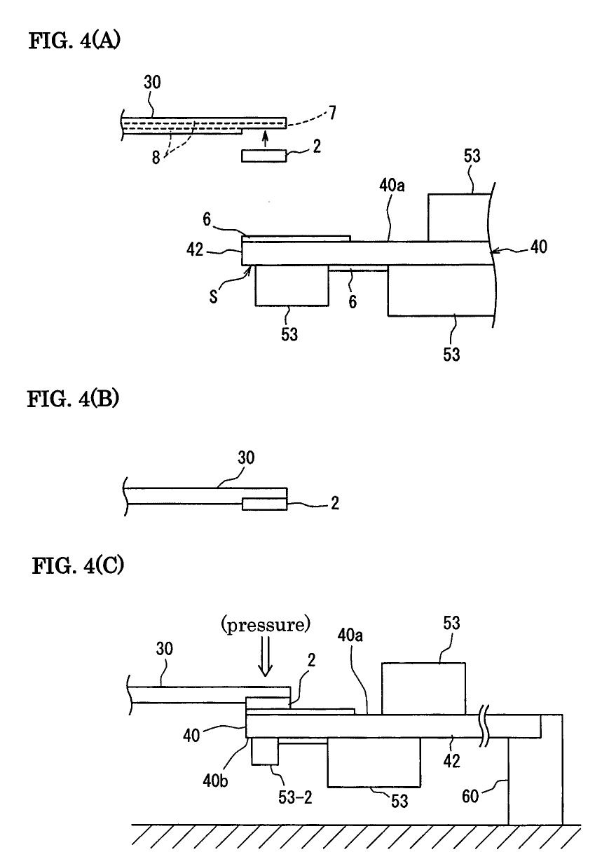

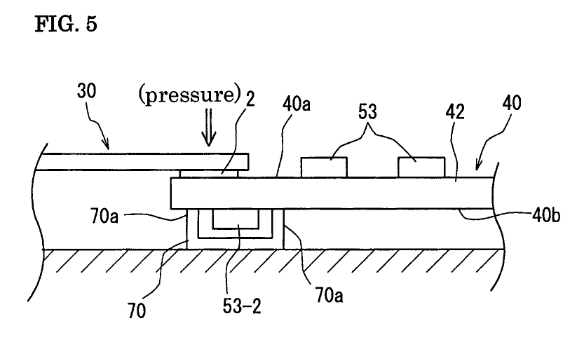

### BRIEF DESCRIPTION OF THE DRAWINGS

[FIG. 1] A schematic diagram showing the whole of a print circuit-board module of the present embodiment.

[FIG. 2] A sectional view of the main PCB of FIG. 1.

[FIG. 3(A)] A schematic sectional view showing a condition existing before a PCB and a FPC are connected using an anisotropic conductive adhesive.

[FIG. 3(B)] An enlarged view showing a metal powder in the anisotropic conductive adhesive.

[FIG. 3(C)] A schematic sectional view showing a condition existing after the PCB and the FPC are connected using the anisotropic conductive adhesive.

[FIG. 4(A)] A schematic drawing showing a step of connection made using an anisotropic conductive adhesive.

[FIG. 4(B)] A schematic drawing showing a step of connection made using an anisotropic conductive adhesive.

[FIG. 4(C)] A schematic drawing showing a step of connection made using an anisotropic conductive adhesive.

[FIG. 5] A schematic drawing showing a modified example of FIG. 4(C).

### EXPLANATION OF REFERENCED NUMERALS

1 print circuit-board module;

2 anisotropic conductive adhesive;

3 binder resin;

4 metal powder;

4a metal particle

6, 7 conductor wiring;

8 coverlay film;

30 (30-1 to 30-6) FPC;

40 (40-1 to 40-5) PCB

40a surface;

40b rear surface;

53 electronic part to be mounted

53-2 part mounted on the rear surface

### BEST MODE FOR IMPLEMENTING THE INVENTION

Hereinafter, embodiments of the present invention will be described referring to the drawings.

FIGS. 1 to 5 show embodiments of a print circuit-board module 1 housed in mobile phone equipment.

In the print circuit-board module 1 shown in FIG. 1, conductor wirings of FPCs 30 (30-1 to 30-6) are connected, each using an anisotropic conductive adhesive 2, respectively with conductor wirings at electrical connection parts P (P1 to P11) on upper surfaces 40a of a plurality of PCBs 40 (40-1 to 40-5) on which parts consisting of electronic and electrical parts are mounted.

In FIG. 1, 40-1 indicates a main PCB having a large-sized square shape. Conductor wirings (not illustrated), which extend to the edges at three sides of the main PCB40-1, are connected with conductor wirings (not illustrated) at electrical connection parts P1 to P4 existing at one end of three FPCs 30-1 to 30-4. The conductor wiring at the other end of the FPC 30-1 is connected with a conductor wiring of a sub-PCB 40-2 at an electrical connection part P5, and the conductor wiring at the other end of the FPC 30-2 is connected with a sub-PCB 40-3 at an electrical connection part P6. The sub-PCB 40-3 is connected to one end of a FPC 30-5 at an electrical connection part P7, and the other end of the FPC 30-5 is connected at an electrical connection part P8 to a PCB 40-4 on which in-camera 55 is mounted.

The other end of the FPC 30-3 is connected with a main display 56 at an electrical connection part P9, and the other end of the FPC 30-4 is connected with a sub-display 57 at an electrical connection part P10. Moreover, a wiring 60 which is connected through a connector with the main PCB 40-1 is connected to a PCB 40-5 through a connector, and the PCB 40-5 is also connected with a FPC 30-6 through an electrical connection part P11, and the FPC 30-6 is connected with PCB 40-6. In the figure, 59 is an out-camera.

On each substrate 42 of the main PCBs 40-1 and 40-5, an electronic part 53 is mounted on the surface 40a thereof as shown in FIG. 1, and an electronic part 53 is also mounted on the rear surface 40b respectively as shown in FIG. 2, and moreover electronic parts 53 are mounted on the rear surface at the back opposed to the electrical connection parts P1 to P4, and P11, which are connected to FPCs 30, respectively.

The electronic parts 53 that are mounted on the PCB 40-1 and 40-5 are electronic and electrical parts such as an embedded memory, a power control IC, a power supply control IC, a sound generator IC, a RF-receiving LSI, a RF-transmitting LSI, a switch IC, a power amplifier, etc. Also, the respective substrate of sub-PCBs 40-2 and 40-3 has a given electronic part 53 mounted thereon.

The connecting structure of the electrical connection parts P1 to P11 of the PCB 40 and the FPC 30 is such that the connection is done using an anisotropic conductive adhesive 2 as shown in FIG. 3(A) to FIG. 3(C). The anisotropic conductive adhesive 2 has a structure in which a binder resin 3 mainly made of thermosetting resin includes needle-shaped metal powders 4 consisting of metal particles 4a oriented in the thickness direction X that is a connection direction as shown in FIG. 3(B).

In the present embodiment, the metal powder 4 made of nickel metal particles 4a having a grain size of about 400 nm has a needle-like shape having a diameter D of about 1 μm, a length L of 5 μm, and L/D of about 5. Also, an epoxy resin is used as the binder resin 3, and the filling fraction of the metal powder 4 is 0.05% by volume.

As shown in FIG. 4 (A), the needle-shaped metal powders 4 of the anisotropic conductive adhesive 2 are made continuous in the thickness direction X so that one end thereof contacts a conductor wiring 6 exposed at the surface 40a of the substrate 42 of the PCB 40 while the other end thereof contacts a conductor wiring 7 exposed at one side face of the FPC 30, and the conductor wirings 6 and 7 are electrically connected with the metal powders 4 of the anisotropic conductive adhesive 2. The FPC 30 is structured such that the conductor wiring 7 wired in parallel is covered with a coverlay film 8 consisting of insulative resin, while the conductor wiring 7 is exposed beforehand at the tip part that is to be connected with the PCB 40.

In the PCBs 40 (40-1 and 40-5), as shown in FIG. 2, the FPC 30 is connected to the surface 40a of the substrate 42 through the anisotropic conductive adhesive 2, and electronic parts 53 are mounted beforehand on the rear surface 40b of the substrate 42 at the position S lying at the back opposed to the electrical connection parts P1 to P4, and P11, which are connected with the FPC 30.

Next, the method of connecting the PCB 40 and the FPC 30 will be described. The anisotropic conductive adhesive 2 is such that an anisotropic conductive adhesive 2 having a sheet-like shape is formed beforehand as shown in FIG. 4(A), and in the present embodiment, it has a thickness of about 30 μm. As shown in FIG. 4(B), the anisotropic conductive adhesive 2 is temporarily pasted beforehand to the connection part of the FPC 30 where the conductor wiring 7 is exposed.

Next, as shown in FIG. 4(C), the PCB 40 to be connected with the FPC 30, to which the anisotropic conductive adhesive 2 is adhered, is put on a putting-stand 60 in a manner such that the surface 40a faces upward whereas the rear surface 40b faces downward. In such case, of the electronic parts 53 mounted on the rear surface, the highest electronic part 53-1 is situated at the lowest end. An edge portion of the surface 40a of the PCB 40 is the connection part for connection with the FPC 30, and an electronic part 53-2 is previously mounted on the rear surface 40b at the position S lying at the back opposed to the connection part. The quantity of downward prominence from the substrate 42 of the electron part 53-2 depends on the electronic part 53-2 to be mounted, and in the present embodiment, the quantity of the prominence is lower than that of the electronic part 53-1 having the maximum height, and accordingly there is a space to the bottom end of the putting-stand 60.

In a state where the surface, to which the anisotropic conductive adhesive 2 is adhered, faces downward, the FPC 30 is put on the connection part at the edge of surface 40a of the PCB 40 that is placed on the putting-stand 60, and the anisotropic conductive adhesive 2 is overlaid on the conductor wiring 6 of the PCB 40.

Under such conditions, heating is done at a temperature to cause the binder resin 3 of the anisotropic conductive adhesive 2 to melt, while a pressure of 2 to 0.1 MPa (in the present embodiment: 0.5 MPa) is applied from the above, so that the anisotropic conductive adhesive 2 and the conductor wiring 6 are press-contacted together while the binder resin 3 is adhered to the insulative resin substrate 42 at the portions lying between the conductor wirings 6 of the PCB 40. Thus, the conductor wirings 6 of the PCB 40 and the conductor wirings 7 of the FPC30 are electrically connected through the metal powders 4 of the anisotropic conductive adhesive 2, while the FPC 30 and the PCB40 are adhered together.

Since the pressure applied at the time of the above-mentioned adhesion is 0.5 MPa, the substrate 42 of the PCB 40 supported with the putting-stand 60 can sustain the compressive load thus applied by the pressure, and therefore it is possible to prevent the compressive load from affecting the electronic part 53-2 that is mounted on the rear surface 40b.

When the pressure resistance of the substrate 42 of the PCB 40 is comparatively low such that the substrate 42 cannot sustain compressive load, a load receiving jig 70 is placed under an electronic part 53-2 as shown in FIG. 5 so that supporting members 70a protruding from the load receiving jig 70 are butted against the rear surface 40a of the PCB 40 at positions around the electronic part 53-2 so as to support the PCB 40. In this case, when the applied pressure is as low as 0.5 MPa as mentioned above, the applied compressive load is also low, and accordingly the supporting members 70a can be made thinner. Consequently, it is possible to decrease the space for arranging the supporting members 70a so that there may be little influence on the mounting of the circuit pattern of the rear surface 40b of the PCB 40 and other packaging parts.

The main PCB 40-1 has four parts for connection with the FPCs 30, and on the rear surface 40b at the back opposed to those four parts, there are four regions S, each of which is capable of mounting an electronic part. Therefore, if the number of the electronic parts to be mounted is the same in a case where electronic parts 53 are mounted on these regions, the substrate itself of the PCB 40 can be downsized and consequently the digital camera itself that has the print circuit-board module 1 can also be downsized. On the other hand, if the substrate area is identical, a larger number of electronic parts can be mounted, whereby the multi-functionalization can be achieved. Also, when there are a number of PCBs to be connected with FPCs, the print circuit-board module 1 can significantly be downsized as a whole by miniaturizing each of the PCBs.

The above-described embodiment is a printed circuit board module to be housed in mobile phone equipment. However, a print circuit-board module having a similar embodiment can suitably be used in electronic equipment which needs to be downsized, such as a digital camera, a camcorder, a portable audio player, etc.

In the above-described embodiment, a PCB and a FPC are connected using an anisotropic conductive adhesive; however, it is also possible to adopt a similar structure in a case where a PCB and a FFC are connected. Also, in the embodiment, a metal powder formed in a needle-like shape by combining metal particles of nano-size is used as the anisotropic conductive adhesive; however, other needle-shaped metal powders may be used; it is not limited if the metal powder has a size that is shorter than a dimension between the neighbor conductor wirings.

1. A circuit-board module having connection parts where a conductor wiring of a first circuit board and a conductor wiring of a second circuit board are connected with an anisotropic conductive adhesive, the anisotropic conductive adhesive being made of an insulative resin including needle-shaped or linear chain-shaped metal powders oriented in the thickness direction of the adhesive, and where a part is mounted on at least either one of the first and the second circuit boards, the part being mounted on the rear surface at the back opposed to the surface where the connection part is formed.

2. A circuit-board module according to claim 1, wherein the first circuit board consists of a rigid printed-circuit board having said part mounted thereon, and the second circuit board is a flexible printed-circuit board.

3. Electronic equipment containing a circuit-board module specified in claim 1.

4. A method of manufacturing a circuit-board module specified in claim 1, the method comprising the steps of:
mounting an electronic part on either one of the first circuit board and the second circuit board; and
connecting conductors of the first circuit board and the second circuit board by mutually contacting them on the face opposite to the parts-mounted face through an anisotropic conductive adhesive and by applying thereto a pressure of 2 MPa or less.

5. A method of manufacturing a circuit-board module according to claim 4, wherein the pressure is 0.5 MPa or less.

6. Electronic equipment containing a circuit-board module specified in claim 2.

7. A method of manufacturing a circuit-board module specified in claim 2, the method comprising the steps of:
mounting an electronic part on either one of the first circuit board and the second circuit board; and
connecting conductors of the first circuit board and the second circuit board by mutually contacting them on the face opposite to the parts-mounted face through an anisotropic conductive adhesive and by applying thereto a pressure of 2 MPa or less.

8. A method of manufacturing a circuit-board module according to claim 7, wherein the pressure is 0.5 MPa or less.
